(19) United States
(12) Patent Application Publication
(10) Pub. No.: US 2008/0259676 A1
(43) Pub. Date: Oct. 23, 2008

(54) Integrated Circuit, Memory Module, Method of Operating an Integrated Circuit, Method of Manufacturing an Integrated Circuit, and Computer Program Product

(76) Inventors: Bernhard Ruf, Sauerlach (DE); Michael Kund, Tuntenhausen (DE); Heinz Hoenigschmid, Poecking (DE)

Correspondence Address: SLATER & MATSIL, L.L.P., 17950 PRESTON ROAD, SUITE 1000, DALLAS, TX, 75252, US

(21) Appl. No.: 11/736,439

(22) Filed: Apr. 17, 2007

(51) Int. Cl. G11C 11/34; G11C 11/56; H01L 29/66

(52) U.S. Cl. 365/163; 438/95; 257/E29.166

(57) ABSTRACT

According to one embodiment of the present invention, an integrated circuit is provided which includes a plurality of resistivity changing cells. At least two resistance ranges are assigned to each resistivity changing cell, each resistance range defining a possible state of the resistivity changing cell. The integrated circuit is operable in a cell initializing mode in which initializing signals are applied to the resistivity changing cells. The strengths and durations of the initializing signals are chosen such that the resistance of each resistivity changing cell is shifted into one of the resistance ranges assigned to the resistivity changing cell.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a cross-sectional view of a solid electrolyte memory device set to a first switching state;

FIG. 1B shows a cross-sectional view of a solid electrolyte memory device set to a second switching state;

FIG. 2A shows a schematic view of an integrated circuit according to one embodiment of the present invention;

FIG. 2B shows a schematic view of an integrated circuit according to one embodiment of the present invention;

FIG. 2C shows a schematic view of an integrated circuit according to one embodiment of the present invention;

FIG. 2D shows a schematic view of an integrated circuit according to one embodiment of the present invention;

FIG. 2E shows a schematic view of an integrated circuit according to one embodiment of the present invention;

FIG. 2F shows a schematic view of an integrated circuit according to one embodiment of the present invention;

FIG. 3 shows a flow chart of a method of operating an integrated circuit according to one embodiment of the present invention;

FIG. 4 shows a flow chart of a method of manufacturing an integrated circuit according to one embodiment of the present invention;

FIG. 5A shows a manufacturing state of a method of manufacturing an integrated circuit according to one embodiment of the present invention;

FIG. 5B shows a manufacturing state of a method of manufacturing an integrated circuit according to one embodiment of the present invention;

FIG. 5C shows a manufacturing state of a method of manufacturing an integrated circuit according to one embodiment of the present invention;

FIG. 5D shows a manufacturing state of a method of manufacturing an integrated circuit according to one embodiment of the present invention;

FIG. 5E shows a manufacturing state of a method of manufacturing an integrated circuit according to one embodiment of the present invention;

FIG. 6 shows a flow chart of a method of operating an integrated circuit according to one embodiment of the present invention;

FIG. 7 shows a flow chart of a method of operating an integrated circuit according to one embodiment of the present invention;

FIG. 8A shows a resistance distribution of an integrated circuit before applying a method of operating an integrated circuit according to one embodiment of the present invention;

FIG. 8B shows a resistance distribution after having applied a method of operating an integrated circuit according to one embodiment of the present invention;

FIG. 9A shows a memory module according to one embodiment of the present invention;

FIG. 9B shows a stacked memory module according to one embodiment of the present invention;

FIG. 10 shows a cross-sectional view of a phase changing memory cell;

FIG. 11 shows a schematic drawing of an integrated circuit;

FIG. 12A shows a cross-sectional view of a carbon memory cell set to a first switching state;

FIG. 12B shows a cross-sectional view of a carbon memory cell set to a second switching state;

FIG. 13A shows a schematic drawing of a resistivity changing memory cell; and

FIG. 13B shows a schematic drawing of a resistivity changing memory cell.

### DETAILED DESCRIPTION OF ILLUSTRATIVE EMBODIMENTS

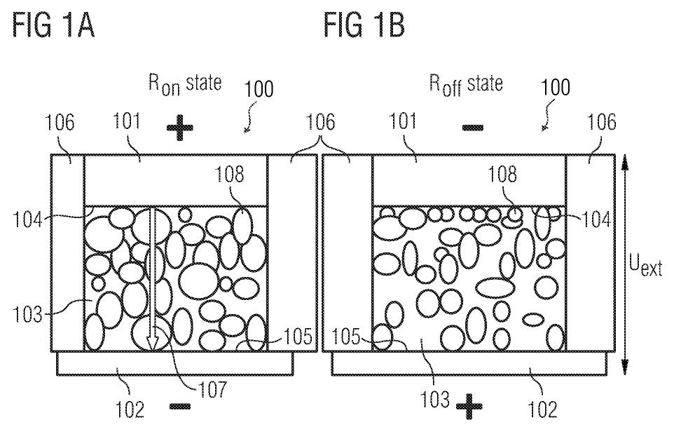

Since the embodiments of the present invention can be applied to solid electrolyte devices like CBRAM (conductive bridging random access memory) devices, in the following description, making reference to FIGS. 1A and 1B, a basic principle underlying embodiments of CBRAM devices will be explained.

As shown in FIG. 1A, a CBRAM cell 100 includes a first electrode 101 a second electrode 102, and an solid electrolyte block (in the following also referred to as ion conductor block) 103 which is the active material and which is sandwiched between the first electrode 101 and the second electrode 102. The first electrode 101 contacts a first surface 104 of the ion conductor block 103, the second electrode 102 contacts a second surface 105 of the ion conductor block 103. The ion conductor block 103 is isolated against its environment by an isolation structure 106. The first surface 104 usually is the top surface, the second surface 105 the bottom surface of the ion conductor 103. In the same way, the first electrode 101 generally is the top electrode, and the second electrode 102 the bottom electrode of the CBRAM cell. One of the first electrode 101 and the second electrode 102 is a reactive electrode, the other one an inert electrode. Here, the first electrode 101 is the reactive electrode, and the second electrode 102 is the inert electrode. In this example, the first electrode 101 includes silver (Ag), the ion conductor block 103 includes silver-doped chalcogenide material, the second electrode 102 includes tungsten (W), and the isolation structure 106 includes SiO₂. The present invention is however not restricted to these materials. For example, the first electrode 101 may alternatively or additionally include copper (Cu), and the ion conductor block 103 may alternatively or additionally include copper-doped chalcogenide material. Further, the second electrode 102 may alternatively or additionally include nickel (Ni) or platinum (Pt).

If a voltage as indicated in FIG. 1A is applied across the ion conductor block 103, a redox reaction is initiated which drives Ag⁺ ions out of the first electrode 101 into the ion conductor block 103 where they are reduced to Ag, thereby forming Ag rich clusters 108 within the ion conductor block 103. If the voltage applied across the ion conductor block 103 is applied for a long period of time, the size and the number of Ag rich clusters within the ion conductor block 103 is increased to such an extent that a conductive bridge 107 between the first electrode 101 and the second electrode 102 is formed. In case that a voltage is applied across the ion conductor 103 as shown in FIG. 1B (inverse voltage compared to the voltage applied in FIG. 1A), a redox reaction is initiated which drives Ag⁺ ions out of the ion conductor block 103 into the first electrode 101 where they are reduced to Ag. As a consequence, the size and the number of Ag rich clusters within the ion conductor block 103 is reduced, thereby erasing the conductive bridge 107.

In order to determine the current memory status of a CBRAM cell, for example, a sensing current is routed through the CBRAM cell. The sensing current experiences a high resistance in case no conductive bridge 107 exists within the CBRAM cell, and experiences a low resistance in case a conductive bridge 107 exists within the CBRAM cell. A high resistance may, for example, represent “0”, whereas a low resistance represents “1”, or vice versa. The memory status detection may also be carried out using sensing voltages.

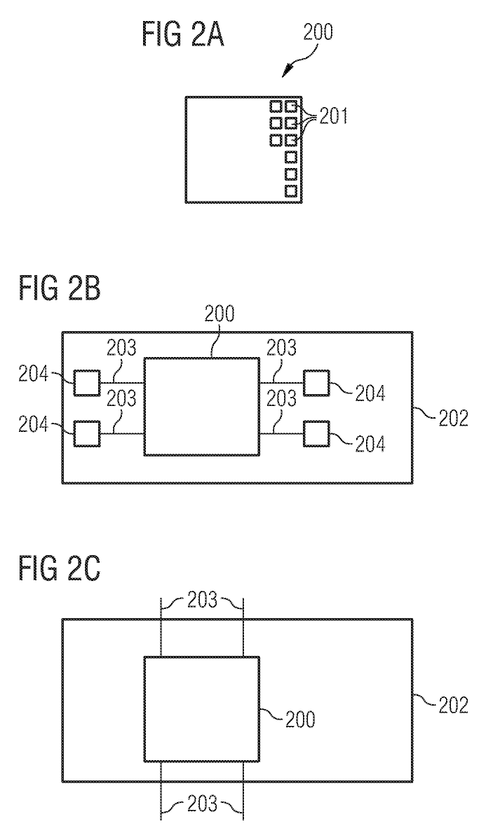

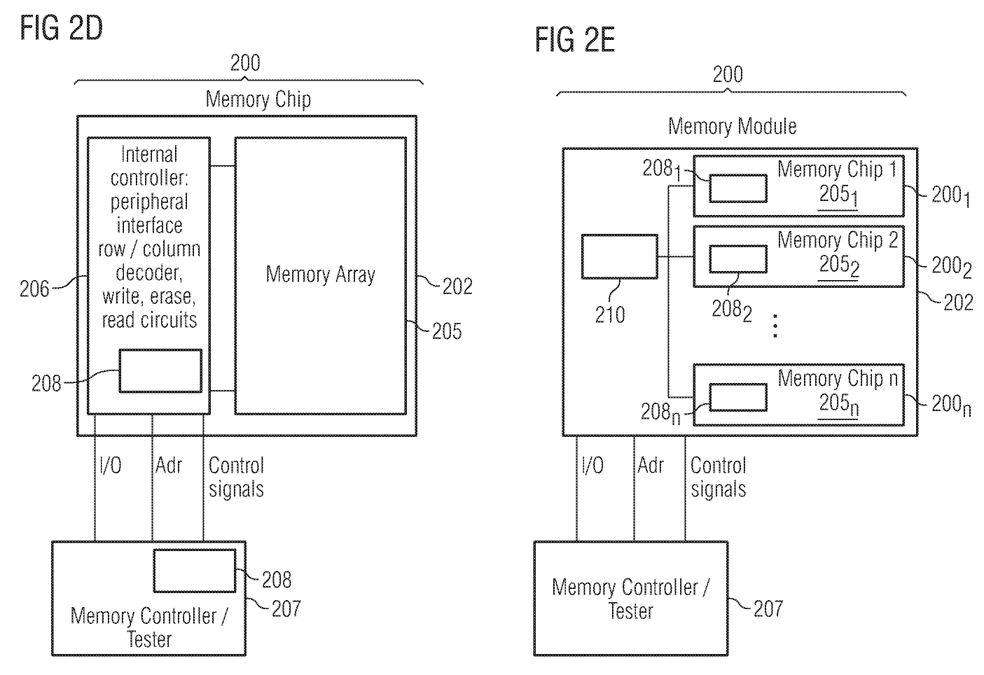

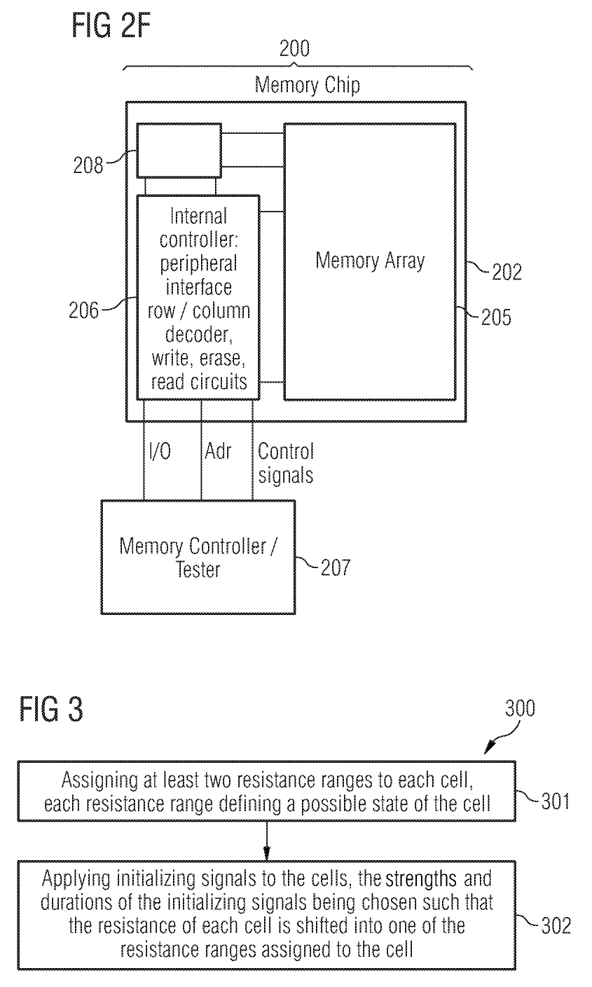

FIG. 2A shows an integrated circuit 200 including a plurality of resistivity changing cells 201. At least two resistance ranges are assigned to each cell 201, wherein each resistance range defines a possible state of the cell 201. The integrated circuit 200 is operable in a cell initializing mode in which initializing signals are applied to the cells 201. The strengths durations of the initializing signals are chosen such that the resistance of each cell 201 is shifted into one of the resistance ranges assigned to the cell 201.

Generally, integrated circuits 200 including resistivity changing cells 201 are operated by changing the states of the cells 201 and by reading the states of the cells 201. In order to change/read the states of the cells 201, normally programming signals or sensing signals of fixed strengths and/or durations are used. That is, an individual programming signal of a fixed strength and duration is assigned to each “allowed” state of the cells 201. Further, an individual sensing signal of a fixed strength and duration is assigned to each “allowed” state of the cells 201. The use of programming signals/sensing signals of fixed strengths and durations however causes problems if the state of at least one cell 201 is a “non-allowed” state which may, for example, occur after having terminated a manufacturing process of the cells 201/integrated circuit 200. Typically, the resistances of a significant amount of cells lie outside of the resistance ranges representing the “allowed” states. However, if the resistance of a cell 201 lies outside of the resistance range into which it should fall, it may happen that the programming signals of fixed strengths and durations may not be capable of transforming the resistance into an “allowed” resistance, i.e., may not be capable of transforming a “not allowed” state into an “allowed” state. In an analogous manner, the same holds true for sensing signals. As a consequence, a cell 201 may be judged to be defective although it is not.

According to one embodiment of the present invention, the strengths and durations of the initializing signals are chosen such that it is guaranteed that after the initializing process all cells 201 (apart from actual defective cells) have “allowed” states. In order to achieve this, according to one embodiment of the present invention, the strengths and durations of the initializing signals at least partially differ from the fixed strengths and durations of programming signals or sensing signals used for programming and sensing the states of the cells 201.

According to one embodiment of the present invention, the strengths and durations of the initializing signals are chosen such that the resistances of all cells 201 are shifted into the same resistance range. Alternatively, the resistances of the cells 201 may be shifted into different resistance ranges.

As shown in FIGS. 2B, 2C, and to 2D, the integrated circuit 200 may be surrounded by a circuit housing 202.

As shown in FIGS. 2B, 2C, the integrated circuit 200 may be connected to initializing terminals 203 which receive initializing signals being generated outside the integrated circuit 200 or which receive triggering signals which are generated outside the integrated circuit 200, and which trigger the integrated circuits 200 to generate initializing signals.

In the embodiment shown in FIG. 2B, the initializing terminals 203 are completely located inside the circuit housing 202, whereas in the embodiment shown in FIG. 2C, the initializing terminals 203 are at least partly located outside the circuit housing 202. In the embodiment shown in FIG. 2B, the initializing terminals 203 are connected to initializing pads 204 which facilitate the supply of initializing signals/triggering signals generated outside the circuit housing 202 to the integrated circuits 200. One effect of the embodiment shown in FIG. 2B is that a user of the integrated circuit 200 is not able to supply initializing signals via the initializing terminals 203 to the integrated circuit 200 since the initializing terminals 203 are hidden within the circuit housing 202. Thus, it can be ensured that the integrated circuit 200 is not destroyed by initializing signals/triggering signals which do not comply with corresponding initializing signal/triggering signal requirements. In contrast, in the embodiment shown in FIG. 2C, since the initializing terminals 203 are accessible to the user, the user is capable of performing initializing procedures of the integrated circuits on its own by supplying initializing signals/triggering signals via the initializing terminals 203 to the integrated circuits 200.

In the embodiment shown in FIG. 2D, the integrated circuit 200 includes a memory cell array 205 and a memory controller 206 coupled to the memory cell array 205. In this embodiment, initializing functionality 208 of the integrated circuit 200 for initializing the memory cells 201 is located within the memory controller 206. Additionally, initializing functionality 208 of the integrated circuit for initializing the memory cells is located within a memory controller 207 located outside the circuit housing 202.

FIG. 2E shows an embodiment where the integrated circuit 200 (which may be interpreted as an integrated circuit module) is split into n integrated circuit units 200₁ to 200ₙ, wherein each integrated circuit unit 200₁ to 200ₙ includes one of n initializing functionality units 208₁ to 208ₙ and one of n memory cell array units 205₁, to 205ₙ. Further, initializing functionality 208 which is connected to all integrated circuit units 200₁ to 200ₙ is provided outside the integrated circuit units 200₁ to 200ₙ, however inside the circuit housing 202.

FIG. 2F shows an embodiment which is similar to the embodiment shown in FIG. 2D. However, the initializing functionality 208 is located outside the memory controller 206, however inside the circuit housing 202. Further, no initializing functionality 208 is located within the memory controller 207.

According to one embodiment of the present invention, the cells 201 are resistivity changing memory cells.

An embodiment of the invention provides a circuit means including a plurality of resistivity changing means, wherein at least two resistance ranges are assigned to each resistivity changing means, each resistance range defining a possible state of the resistivity changing means. The circuit means is operable in a memory means initializing mode in which initializing signals are applied to the plurality of resistivity changing means. The strengths and durations of the initializing signals are chosen such that the resistance of each resistivity changing means is shifted into one of the resistance ranges assigned to the resistivity changing means.

According to one embodiment of the invention, the circuit means is an integrated circuit 200 and the resistivity changing means are resistivity changing memory cells, for example, solid electrolyte memory cells (e.g., CBRAM cells), magneto-resistive memory cells (e.g., MRAM cells), phase changing memory cells (e.g., PCRAM cells), organic memory cells (e.g., ORAM cells), and the like.

According to one embodiment of the present invention, a memory module is provided comprising at least one integrated circuit according to one embodiment of the present invention. According to one embodiment of the present invention, the memory module is stackable.

FIG. 3 shows a method 300 of operating an integrated circuit including a plurality of resistivity changing cells according to one embodiment of the present invention.

At 301, at least two resistance ranges are assigned to each resistivity changing cell, each resistance range defining a possible state of the resistivity changing cell. The resistance ranges assigned may be determined before starting the method 300 or during carrying out the method 300.

At 302, initializing signals are applied to the resistivity changing cells, the strengths and durations of the initializing signals being chosen such that the resistance of each resistivity changing cell is shifted into one of the resistance ranges assigned to the resistivity changing cell.

According to one embodiment of the present invention, 302 includes generating initializing signals outside the integrated circuit and supplying the generated initializing signals to the integrated circuit.

According to one embodiment of the present invention, 302 includes supplying triggering signals triggering the integrated circuit to generate initializing signals to the integrated circuit.

According to one embodiment of the present invention, 302 includes simultaneously setting the cells to a common resistance value by applying respective initializing voltages or initializing currents to the cells.

According to one embodiment of the present invention, 302 includes setting the cells to a common resistance value by applying a constant initializing current or constant initializing voltage to each cell for a period of time which is larger than the period of time used for reading or programming the states of the cells. According to one embodiment of the present invention, the period of time for applying a constant initializing current or constant initializing voltage is 100 μs up to 100 ms. In contrast, according to one embodiment of the present invention, the period of time used for reading or programming the states of the cells is 10 ns up to 10 μs. According to one embodiment of the present invention, initializing voltages used are about 500 mV. They may, for example, be used in combination with initializing durations of 10 ms.

According to one embodiment of the present invention, the method 300 includes assigning a select device to each cell, the resistance value of the cells being controlled by using the select devices as voltages dividers.

According to one embodiment of the present invention, a method of operating a plurality of resistivity changing memory cells is provided. The method includes assigning at least two resistance ranges to each resistivity changing cell, each resistance range defining a possible state of the resistivity changing cell, and applying initializing signals to the resistivity changing cells, the strengths and durations of the initializing signals being chosen such that the resistance of each resistivity changing cell is shifted into one of the resistance ranges assigned to the resistivity changing cell.

All embodiments discussed in conjunction with the method of operating an integrated circuit can also be applied to the method of operating the plurality of memory cells.

According to one embodiment of the present invention, a computer program product is provided, configured to perform, when being carried out on a computing device, a method according to any embodiment of the present invention. An embodiment of the invention provides further a data carrier configured to store a computer program product according to one embodiment of the present invention.

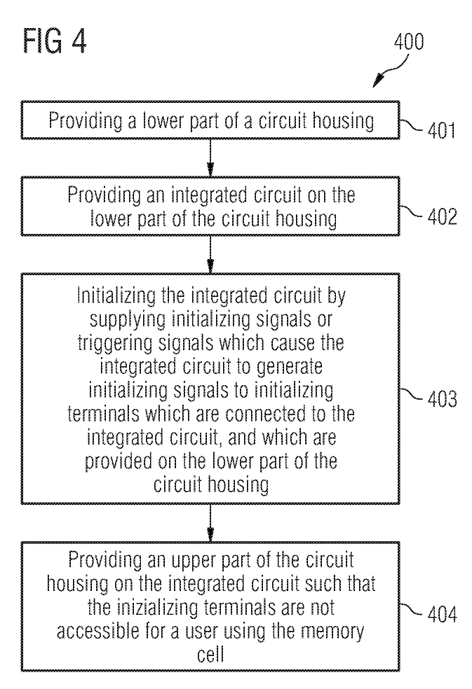

FIG. 4 shows a method 400 of manufacturing an integrated circuit according to one embodiment of the present invention.

At 401, a lower part of a circuit housing is provided.

At 402, an integrated circuit is provided on the lower part of the circuit housing.

At 403, the integrated circuit is initialized by supplying initializing signals or triggering signals which cause the integrated circuit to generate initializing signals to initializing terminals which are connected to the integrated circuit, and which are provided on the lower part of the circuit housing.

At 404, an upper part of the circuit housing is provided on the integrated circuit such that the initializing terminals are not accessible for a user using the memory cell.

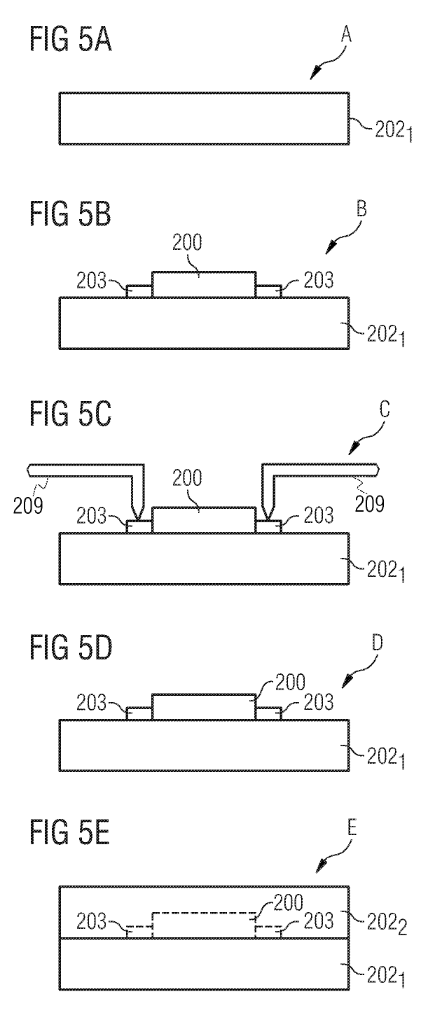

An example of this embodiment of manufacturing an integrated circuit will be explained in the following description while making reference to FIGS. 5A to 5E.

FIG. 5A shows a manufacturing stage A in which a lower part 202₁ of a circuit housing has been provided. FIG. 5B shows a manufacturing stage B in which an integrated circuit 200 has been provided on the lower part 202₁ of the circuit housing. Further, initializing terminals 203 which are connected to the integrated circuit 200 are provided on the lower part 202₁ of the circuit housing. FIG. 5C shows a manufacturing stage C in which the integrated circuit 200 is initialized by supplying initializing signals or triggering signals which cause the integrated circuit to generate initializing signals to the initializing terminals 203. The initializing signals/triggering signals are supplied via conductive lines 209 to the initializing terminals 203. After having initialized the integrated circuit 200 the conductive lines 209 are removed (manufacturing stage D shown in FIG. 5D). FIG. 5E shows a processing stage E in which an upper part 202₂ of the circuit housing has been provided on the lower part 202₁ of the circuit housing such that the integrated circuit 200 is encapsulated by the lower part 202₁ and the upper part 202₂ of the circuit housing.

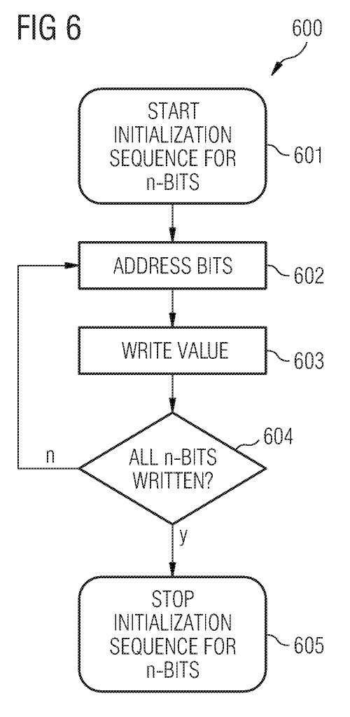

FIG. 6 shows a method 600 of operating an integrated circuit according to one embodiment of the present invention.

At 601, an initialization sequence for initializing n bits is started.

At 602, the n bits to be initialized are addressed, i.e., for each bit to be written the corresponding memory cell is determined.

At 603, the resistances of the memory cells corresponding to the bits to be initialized are set to resistance initializing values representing bit initializing values. Step 603 may be carried out simultaneously for all n bits or successively, i.e., bit per bit.

At 604, it is determined whether all n bits have already been initialized.

In an embodiment of the invention, 602 and 603 are repeated until all bits have been initialized. In this case, the initialization sequence is terminated at 605.

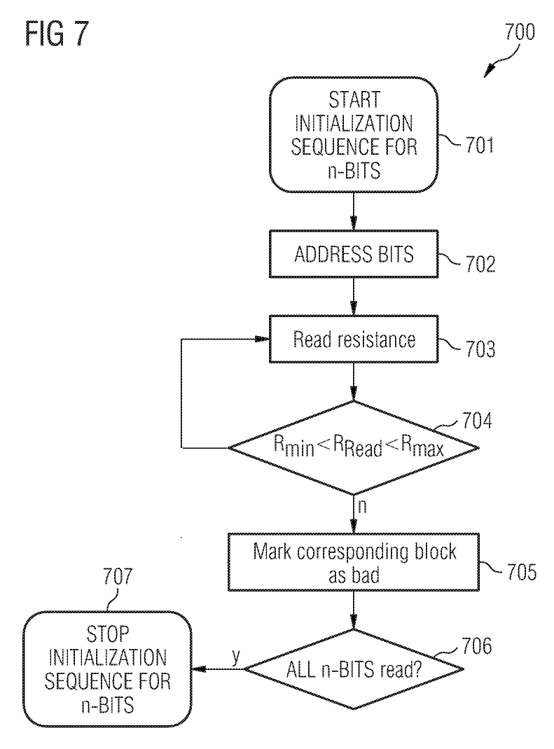

FIG. 7 shows a method 700 of operating an integrated circuit according to one embodiment of the present invention.

At 701, an initialization sequence for initializing n bits is started.

At 702, the n bits to be initialized are addressed, i.e., for each bit to be read the corresponding memory cell is determined.

At 703, one of the n bits is read, i.e., the resistance representing the bit is read. Alternatively, all bits are read simultaneously.

At 704, it is determined whether the resistance read at 703 lies within a resistance range. If this is the case, i.e., if the resistance which has been read represents the correct memory state, the method returns to 703. However, if the resistance does not lie within the resistance range, the corresponding memory cell block including the memory cell is marked a bad memory cell block. 703 to 705 are repeated until the resistances of all n bits have been read. As soon as all n bits have been read, this is recognized at 706, and the initialization sequence is terminated at 707.

Method 700 may, for example, be carried out before carrying out the method 600 shown in FIG. 6. For example, a bad block detected during 705 in the method 700 shown in FIG. 7 may be initialized using the method 600 shown in FIG. 6. Or, a block of memory cells initialized using the method 600 may be tested using the method 700 whether the initialization process was successful.

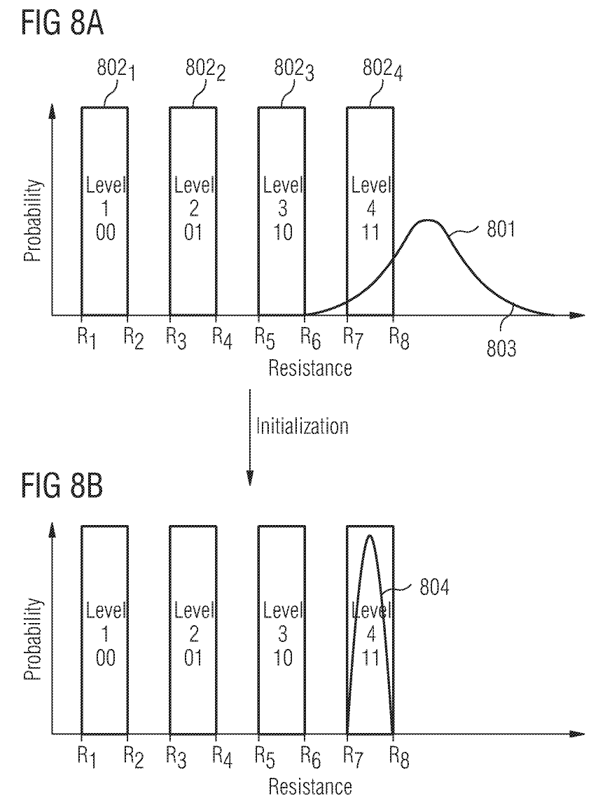

FIG. 8A shows a resistance distribution 801 of cells of an integrated circuit which may occur after having terminated the manufacturing process of the integrated circuit. Here, it is assumed that each cell of the integrated circuit can adopt four different states, i.e., resistances, namely a first state 802₁, a second state 802₂, a third state 802₃ and fourth state 802₄. As can be derived from the resistance distribution 801, most of the resistances do not lie within the resistance ranges 802, i.e., lie outside of the resistance ranges 802. This means that it may not be possible to shift the resistances into the resistance ranges 802 using “normal” programming signals. For example, the strengths of the programming signals may not be strong enough to transform a cell resistance indicated by reference numeral 803 into a cell resistance lying within a resistance range 802. As a consequence, the memory cell having the resistance 803 may be judged as being defect, although this is not the case.

According to one embodiment of the present invention, the resistance distribution 801 is transformed into an initialized resistance distribution 804 as shown in FIG. 8B. Here, the initialized resistance distribution 804 completely lies within the fourth resistance range 802₄. However, the present invention is not restricted thereto. It may also be possible to transform the resistance distribution 801 into an initialized resistance distribution 804 lying within one of the first to third resistance ranges 802₁ to 802₃, or to split the resistance distribution 801 into several initialized resistance distributions, each initialized resistance distribution lying within one of the first to fourth resistance range 802₁ to 802₄. The effect of an initialized distribution/several initialized distributions is that “normal” programming voltages can be used in order to shift a resistance value from one resistance range 802 to another resistance range 802. In order to transform the resistance distribution 801 into the initialized resistance distribution 804, according to one embodiment of the present invention, programming signals may be used, the strengths and durations of which do not conform with other strengths and durations of the “normal” programming signals.

To give an example, according to one embodiment of the invention, it is assumed that the first resistance range 802₁ extends from R₁ to R₂, wherein R₁ is 10 kOhm, and R₂ is 20 kOhm, the second resistance range 802₂ extends from R₃ to R₄, wherein R₃ is 30 kOhm, and R₄ is 40 kOhm, the third resistance range 802₃ extends from R₅ to R₆, wherein R₅ is 50 kOhm, and R₂ is 60 kOhm, and the fourth resistance range 802₄ extends from R₇ to R₈, wherein R₇ is 70 kOhm, and R₈ is 80 kOhm. Further assuming that the resistivity changing memory cells are solid electrolyte memory cells, resistances lower than 5 kOhm and higher than 1 MOhm would, for example, be “problematic” resistance values, since typical initializing voltages of, e.g., 1.5V and typical initializing durations of, e.g., 100 ns normally used to shift a resistance value from one resistance range 802 to another resistance range 802 may not be capable of shifting a resistance value below 5 kOhm or above 1 MOhm into one of the first to fourth resistance range 802₁ to 802₄. In contrast, according to one embodiment of the present invention, using initializing voltages of, e.g., 500 mV and initializing durations of, e.g., 10 ms may be capable of shifting a resistance value below 5 kOhm or above 1 MOhm into one of the first to fourth resistance range 802₁ to 802₄. It is to be understood that the above described example is not to be understood as limiting. Exact resistance values/initializing values are dependent on the design of the integrated circuit used, and the type of memory technology (CBRAM, MRAM, PCRAM, used, and may therefore strongly differ from each other.

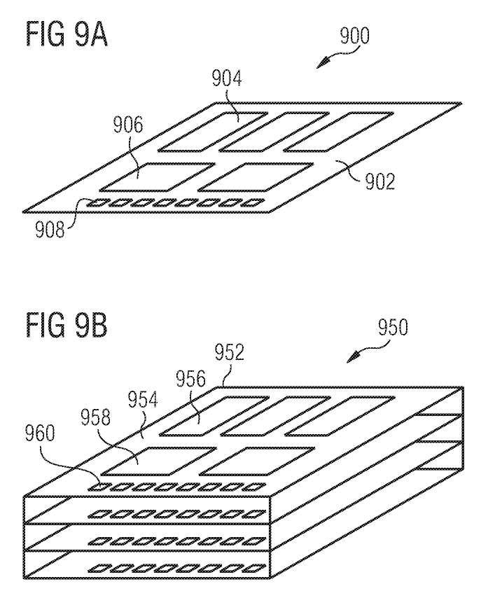

As shown in FIGS. 9A and 9B, in some embodiments, memory devices or integrated circuits such as those described herein may be used in modules. In FIG. 9A, a memory module 900 is shown, on which one or more integrated circuits or memory devices 904 are arranged on a substrate 902. The integrated circuits/memory devices 904 may include numerous memory cells in accordance with an embodiment of the invention. The memory module 900 may also include one or more electronic devices 906, which may include memory, processing circuitry, control circuitry, addressing circuitry, bus interconnection circuitry, or other circuitry or electronic devices that may be combined on a module with a memory device, such as the integrated circuits/memory devices 904. Additionally, the memory module 900 includes multiple electrical connections 908, which may be used to connect the memory module 900 to other electronic components, including other modules.

As shown in FIG. 9B, in some embodiments, these modules may be stackable, to form a stack 950. For example, a stackable memory module 952 may contain one or more memory devices 956, arranged on a stackable substrate 954. The memory device 956 contains memory cells that employ memory elements in accordance with an embodiment of the invention. The stackable memory module 952 may also include one or more electronic devices 958, which may include memory, processing circuitry, control circuitry, addressing circuitry, bus interconnection circuitry, or other circuitry or electronic devices that may be combined on a module with a memory device, such as the memory device 956. Electrical connections 960 are used to connect the stackable memory module 952 with other modules in the stack 950, or with other electronic devices. Other modules in the stack 950 may include additional stackable memory modules, similar to the stackable memory module 952 described above, or other types of stackable modules, such as stackable processing modules, control modules, communication modules, or other modules containing electronic components.

According to one embodiment of the invention, the resistivity changing (memory) cells are phase changing (memory) cells that include a phase changing material. The phase changing material can be switched between at least two different crystallization states (i.e., the phase changing material may adopt at least two different degrees of crystallization), wherein each crystallization state may be used to represent a memory state. When the number of possible crystallization states is two, the crystallization state having a high degree of crystallization is also referred to as a “crystalline state”, whereas the crystallization state having a low degree of crystallization is also referred to as an “amorphous state”. Different crystallization states can be distinguished from each other by their differing electrical properties, and in particular by their different resistances. For example, a crystallization state having a high degree of crystallization (ordered atomic structure) generally has a lower resistance than a crystallization state having a low degree of crystallization (disordered atomic structure). For sake of simplicity, it will be assumed in the following that the phase changing material can adopt two crystallization states (an “amorphous state” and a “crystalline state”), however it will be understood that additional intermediate states may also be used.

Phase changing memory cells may change from the amorphous state to the crystalline state (and vice versa) due to temperature changes of the phase changing material. These temperature changes may be caused using different approaches. For example, a current may be driven through the phase changing material (or a voltage may be applied across the phase changing material). Alternatively, a current or a voltage may be fed to a resistive heater which is disposed adjacent to the phase changing material. To determine the memory state of a resistivity changing memory cell, a sensing current may be routed through the phase changing material (or a sensing voltage may be applied across the phase changing material), thereby sensing the resistance of the resistivity changing memory cell, which represents the memory state of the memory cell.

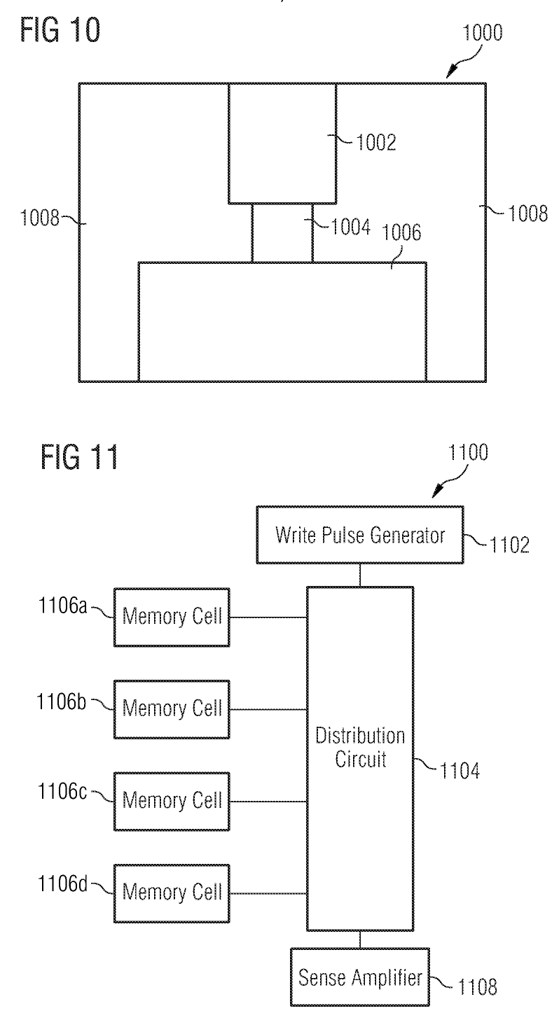

FIG. 10 illustrates a cross-sectional view of an exemplary phase changing memory cell 1000 (active-in-via type). The phase changing memory cell 1000 includes a first electrode 1002, a phase changing material 1004, a second electrode 1006, and an insulating material 1008. The phase changing material 1004 is laterally enclosed by the insulating material 1008. To use the phase changing memory cell in a memory cell, a selection device (not shown), such as a transistor, a diode, or another active device, may be coupled to the first electrode 1002 or to the second electrode 1006 to control the application of a current or a voltage to the phase changing material 1004 via the first electrode 1002 and/or the second electrode 1006. To set the phase changing material 1004 to the crystalline state, a current pulse and/or voltage pulse may be applied to the phase changing material 1004, wherein the pulse parameters are chosen such that the phase changing material 1004 is heated above its crystallization temperature, while keeping the temperature below the melting temperature of the phase changing material 1004. To set the phase changing material 1004 to the amorphous state, a current pulse and/or voltage pulse may be applied to the phase changing material 1004, wherein the pulse parameters are chosen such that the phase changing material 1004 is quickly heated above its melting temperature, and is quickly cooled.

The phase changing material 1004 may include a variety of materials. According to one embodiment, the phase changing material 1004 may include or consist of a chalcogenide alloy that includes one or more cells from group VI of the periodic table. According to another embodiment, the phase changing material 1004 may include or consist of a chalcogenide compound material, such as GeSbTe, SbTe, GeTe or AgInSbTe. According to a further embodiment, the phase changing material 1004 may include or consist of chalcogen free material, such as GeSb, GaSb, InSb, or GeGaInSb. According to still another embodiment, the phase changing material 1004 may include or consist of any suitable material including one or more of the elements Ge, Sb, Te, Ga, Bi, Pb, Sn, Si, P, O, As, In, Se, and S.

According to one embodiment, at least one of the first electrode 1002 and the second electrode 1006 may include or consist of Ti, V, Cr, Zr, Nb, Mo, Hf, Ta, W, or mixtures or alloys thereof. According to another embodiment, at least one of the first electrode 1002 and the second electrode 1006 may include or consist of Ti, V, Cr, Zr, Nb, Mo, Hf, Ta, W and two or more elements selected from the group consisting of B, C, N, O, Al, Si, P, S, and/or mixtures and alloys thereof. Examples of such materials include TiCN, TiAlN, TiSiN, W—Al₂O₃ and Cr—Al₂O₃.

FIG. 11 illustrates a block diagram of a memory device 1100 including a write pulse generator 1102, a distribution circuit 1104, phase changing memory cells 1106a, 1106b, 1106c, 1106d (for example, phase changing memory cells 1000 as shown in FIG. 10), and a sense amplifier 1108. According to one embodiment, a write pulse generator 1102 generates current pulses or voltage pulses that are supplied to the phase changing memory cells 1106a, 1106b, 1106c, 1106d via the distribution circuit 1104, thereby programming the memory states of the phase changing memory cells 1106a, 1106b, 1106c, 1106d. According to one embodiment, the distribution circuit 1104 includes a plurality of transistors that supply direct current pulses or direct voltage pulses to the phase changing memory cells 1106a, 1106b, 1106c, 1106d or to heaters being disposed adjacent to the phase changing memory cells 1106a, 1106b, 1106c, 1106d.

As already indicated, the phase changing material of the phase changing memory cells 1106a, 1106b, 1106c, 1106d may be changed from the amorphous state to the crystalline state (or vice versa) under the influence of a temperature change. More generally, the phase changing material may be changed from a first degree of crystallization to a second degree of crystallization (or vice versa) under the influence of a temperature change. For example, a bit value “0” may be assigned to the first (low) degree of crystallization, and a bit value “1” may be assigned to the second (high) degree of crystallization. Since different degrees of crystallization imply different electrical resistances, the sense amplifier 1108 is capable of determining the memory state of one of the phase changing memory cells 1106a, 1106b, 1106c, or 1106d in dependence on the resistance of the phase changing material.

To achieve high memory densities, the phase changing memory cells 1106a, 1106b, 1106c, 1106d may be capable of storing multiple bits of data, i.e., the phase changing material may be programmed to more than two resistance values. For example, if a phase changing memory cell 1106a, 1106b, 1106c, 1106d is programmed to one of three possible resistance levels, 1.5 bits of data per memory cell can be stored. If the phase changing memory cell is programmed to one of four possible resistance levels, two bits of data per memory cell can be stored, and so on.

The embodiment shown in FIG. 11 may also be applied in a similar manner to other types of resistivity changing memory cells like programmable metallization cells (PMCs), magento-resistive memory cells (e.g., MRAMs) or organic memory cells (e.g., ORAMs).

Another type of resistivity changing (memory) cell may be formed using carbon as a resistivity changing material. Generally, amorphous carbon that is rich is sp³-hybridized carbon (i.e., tetrahedrally bonded carbon) has a high resistivity, while amorphous carbon that is rich in sp²-hybridized carbon (i.e., trigonally bonded carbon) has a low resistivity. This difference in resistivity can be used in a resistivity changing memory cell.

In one embodiment, a carbon memory cell may be formed in a manner similar to that described above with reference to phase changing memory cells. A temperature-induced phase change between an sp³-rich phase and an sp²-rich phase may be used to change the resistivity of an amorphous carbon material. These differing resistivities may be used to represent different memory states. For example, a high resistance sp³-rich phase can be used to represent a “0”, and a low resistance sp²-rich phase can be used to represent a “1”. It will be understood that intermediate resistance states may be used to represent multiple bits, as discussed above.

Generally, in this type of carbon memory cell, application of a first temperature causes the conversion of high resistivity sp³-rich amorphous carbon to relatively low resistivity sp²-rich amorphous carbon. This conversion can be reversed by application of a second temperature, which is generally higher than the first temperature. As discussed above, these temperatures may be provided, for example, by applying a current and/or voltage pulse to the carbon material. Alternatively, the temperatures can be provided by using a resistive heater which is disposed adjacent to the carbon material.

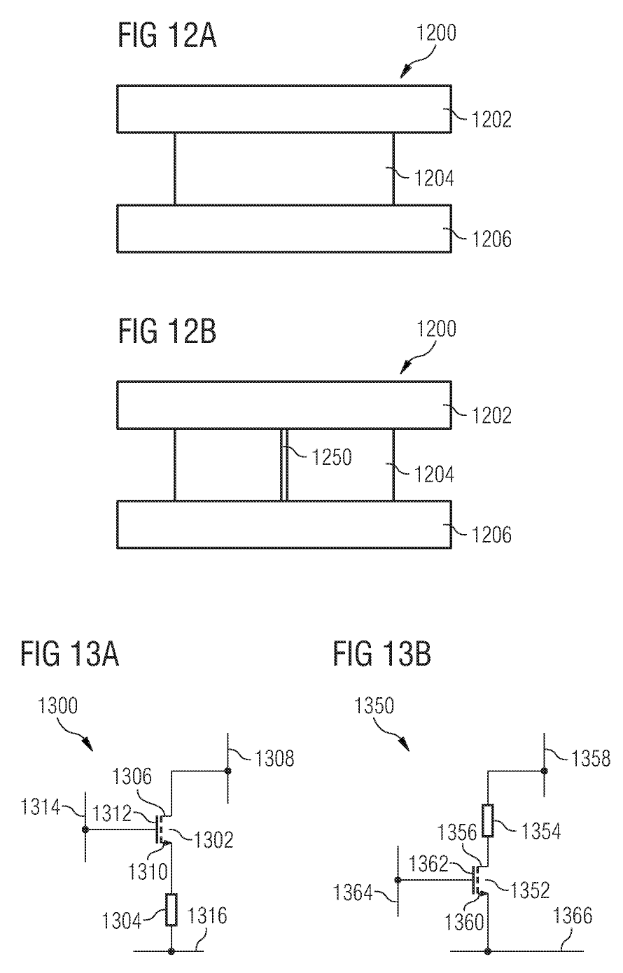

Another way in which resistivity changes in amorphous carbon can be used to store information is by field-strength induced growth of a conductive path in an insulating amorphous carbon film. For example, applying voltage or current pulses may cause the formation of a conductive sp² filament in insulating sp³-rich amorphous carbon. The operation of this type of resistive carbon memory is illustrated in FIGS. 12A and 12B.

FIG. 12A shows a carbon memory cell 1200 that includes a top contact 1202, a carbon storage layer 1204 including an insulating amorphous carbon material rich in sp³-hybridized carbon atoms, and a bottom contact 1206. As shown in FIG. 12B, by forcing a current (or voltage) through the carbon storage layer 1204, an sp² filament 1250 can be formed in the sp³-rich carbon storage layer 1204, changing the resistivity of the memory cell. Application of a current (or voltage) pulse with higher energy (or, in some embodiments, reversed polarity) may destroy the sp² filament 1250, increasing the resistance of the carbon storage layer 1204. As discussed above, these changes in the resistance of the carbon storage layer 1204 can be used to store information, with, for example, a high resistance state representing a “0” and a low resistance state representing a “1”. Additionally, in some embodiments, intermediate degrees of filament formation or formation of multiple filaments in the sp³-rich carbon film may be used to provide multiple varying resistivity levels, which may be used to represent multiple bits of information in a carbon memory cell. In some embodiments, alternating layers of sp³-rich carbon and sp²-rich carbon may be used to enhance the formation of conductive filaments through the sp³-rich layers, reducing the current and/or voltage that may be used to write a value to this type of carbon memory.

Resistivity changing memory cells, such as the phase changing memory cells and carbon memory cells described above, may include a transistor, diode, or other active component for selecting the memory cell. FIG. 13A shows a schematic representation of such a memory cell that uses a resistivity changing memory element. The memory cell 1300 includes a select transistor 1302 and a resistivity changing memory cell 1304. The select transistor 1302 includes a source 1306 that is connected to a bit line 1308, a drain 1310 that is connected to the memory element 1304, and a gate 1312 that is connected to a word line 1314. The resistivity changing memory element 1304 also is connected to a common line 1316, which may be connected to ground, or to other circuitry, such as circuitry (not shown) for determining the resistance of the memory cell 1300, for use in reading. Alternatively, in some configurations, circuitry (not shown) for determining the state of the memory cell 1300 during reading may be connected to the bit line 1308. It should be noted that as used herein the terms connected and coupled are intended to include both direct and indirect connection and coupling, respectively.

To write to the memory cell 1300, the word line 1314 is used to select the memory cell 1300, and a current (or voltage) pulse on the bit line 1308 is applied to the resistivity changing memory element 1304, changing the resistance of the resistivity changing memory element 1304. Similarly, when reading the memory cell 1300, the word line 1314 is used to select the cell 1300, and the bit line 1308 is used to apply a reading voltage (or current) across the resistivity changing memory element 1304 to measure the resistance of the resistivity changing memory element 1304.

The memory cell 1300 may be referred to as a 1T1J cell, because it uses one transistor, and one memory junction (the resistivity changing memory element 1304). Typically, a memory device will include an array of many such cells. It will be understood that other configurations for a 1T1J memory cell, or configurations other than a 1T1J configuration may be used with a resistivity changing memory element. For example, in FIG. 13B, an alternative arrangement for a 1T1J memory cell 1350 is shown, in which a select transistor 1352 and a resistivity changing memory element 1354 have been repositioned with respect to the configuration shown in FIG. 13A. In this alternative configuration, the resistivity changing memory element 1354 is connected to a bit line 1358, and to a source 1356 of the select transistor 1352. A drain 1360 of the select transistor 1352 is connected to a common line 1366, which may be connected to ground, or to other circuitry (not shown), as discussed above. A gate 1362 of the select transistor 1352 is controlled by a word line 1364.

According to one embodiment of the present invention, the resistivity changing memory cells are transition metal oxide (TMO) memory cells.

In the following description, further embodiments of the present invention will be explained in more detail.

Resistive memory devices like CBRAM devices, PCRAM devices or MRAM devices can adopt different electrical resistance states. In the simplest case (1 bit cell) two resistance states can be adopted which will be referred to in the following as Rₒₙ (low resistance state) and as R_{off} (high resistance state). More generally, in the case of a n bit cell (also referred to as multilevel cell (MLC)), 2ⁿ states can be adopted. Using suitable stimulation, it is possible to cause transitions between different resistance states.

A problem is that, after having manufactured the memory device, the resistance states of different cells are not concentrated around a single, sharp resistance level, but generally have a very broad resistance distribution, which may not completely lie within resistance ranges assigned to the resistance states. This undesired distribution may, for example, occur after processing, after warehousing, or after temperature stress which may, for example, occur during “packaging”. In such cases, usually a number of cells have resistance states which are “forbidden” during “normal” operation. Standard access procedures like writing, erasing or reading resistance states may lead to errors which may be desired to be avoided as much as possible.

In order to avoid these problems, an external initialization of the whole array of the memory device may be carried out by a testing system or a memory controller using “regular” writing procedures. An effect of this approach is that the testing system and the memory controller only allow “regular” writing access/reading access. However, regular writing access/reading access may result in a time consuming initializing process of the memory device. Further, the initializing process may not be possible for some cells since they may not be transformable by regular procedures/accesses into “allowed” resistance states. This yields to errors when testing the memory device.

According to one embodiment of the present invention, a special circuit is provided which ensures an optimized (time optimized) initialization of the memory device. The special circuit enables electrical stimulation of all cells or a portion of the cells such that as many cells as possible have an “allowed” resistance level after the initialization process. The special circuit may be completely integrated into the memory device (“on chip”) or may be completely located outside. Even “mixed solutions” may be used. That is, a part of the circuit is located on the chip, and another part is located outside the chip. The initialization should set as many cells as possible to a single defined resistance level. Thus, both a maximum amount of “forbidden” states should be avoided and all “allowed” states should be transformed into exactly one resistance level. This resistance level may, for example, be the highest resistance level (R_{off} in the case of a 1 bit cell). Alternatively, this resistance level may be any resistance level of the 2^{N} possible levels of a multilevel system.

According to one embodiment of the present invention, electrical stimulation processes which are not available during normal operation may be used in order to transform as many cells as possible from a “forbidden” state into “allowed” states as fast as possible.

The triggering of this initialization process may, for example, be included into the power up sequence of the memory device or may be initiated by an external controlling signal or controlling sequence. The initialization during the power up sequence, may be in particular suitable for volatile memories (like DRAM (dynamic random access memory)) since the initial state of the cell is ignored. If non-volatile memories (like FLASH) are used, the initialization process has to be triggered from outside. The initialization may be performed at arbitrary test “insertions” (wafer test, memory device test, module test). In this way, the testing procedure can be optimized. Further, influences resulting from particular processing steps (packaging, warehousing, temperature stress, . . . ) can be studied (“learning”).

According to one embodiment of the present invention, a resistive memory device is initialized such that an undesired resistance distribution of the memory device which leads to errors (during operation) or which complicates testing procedures is transformed into a defined distribution which avoids these effects.

According to one embodiment of the present invention, a special circuit is internally integrated on a memory device chip. The triggering of the initialization process is done by an external memory controller or tester using controlling signals which are sent to the memory device. The memory device may comprise an initializing unit in which the algorithm is implemented, and which transforms as much memory cells as possible into a defined resistance distribution as fast as possible. The end of the initialization process may be signalled via an I/O interface to the tester or the external memory controller.

According to one embodiment of the present invention, a significant part of initialization functionality is located on an external memory controller or tester. A special test mode for initializing allows an operating mode which is not possible for “normal” operation.

According to one embodiment of the present invention, a significant part of initialization functionality is embodied as additional circuit on a memory module instead of on a tester or a memory controller.

As used herein, the terms “connected” and “coupled” are intended to include both direct and indirect connection and coupling, respectively.

In the context of this description chalcogenide material (ion conductor) is to be understood, for example, as any compound containing oxygen, sulphur, selenium, germanium and/or tellurium. In accordance with one embodiment of the invention, the ion conducting material is, for example, a compound, which is made of a chalcogenide and at least one metal of the group I or group II of the periodic system, for example, arsene-trisulfide-silver. Alternatively, the chalcogenide material contains germanium-sulfide (GeS), germanium-selenide (GeSe), tungsten oxide (WOₓ), copper sulfide (CuS) or the like. The ion conducting material may be a solid state electrolyte.

Furthermore, the ion conducting material can be made of a chalcogenide material containing metal ions, wherein the metal ions can be made of a metal, which is selected from a group consisting of silver, copper and zinc or of a combination or an alloy of these metals.

The invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. An integrated circuit comprising a plurality of resistivity changing cells, wherein at least two resistance ranges are assigned to each resistivity changing cell, each resistance range defining a possible state of the resistivity changing cell and wherein the integrated circuit is operable in a cell initializing mode, in which initializing signals are applied to the resistivity changing cells, strengths and durations of the initializing signals being chosen such that the resistance of each resistivity changing cell is shifted into one of the resistance ranges assigned to the resistivity changing cell.

2. The integrated circuit according to claim 1, wherein the strengths and durations of the initializing signals at least partly differ from strengths and durations of programming signals or sensing signals used for programming and sensing the states of the resistivity changing cells.

3. The integrated circuit according to claim 1, wherein the resistances of all resistivity changing cells are shifted into the same resistance range.

4. The integrated circuit according to claim 1, wherein the integrated circuit is connected to initializing terminals that receive initializing signals that are generated outside the integrated circuit, or that receive triggering signals triggering the integrated circuit to generate initializing signals.

5. The integrated circuit according to claim 4, wherein the integrated circuit is surrounded by a circuit housing.

6. The integrated circuit according to claim 5, wherein the initializing terminals are at least partly located outside the circuit housing.

7. The integrated circuit according to claim 5, wherein the initializing terminals are completely located inside the circuit housing.

8. The integrated circuit according to claim 1, wherein the resistivity changing cells comprise memory cells.

9. The integrated circuit according to claim 8, wherein initializing functionality of the integrated circuit initializing the memory cells is at least partly located within a memory controller that is located within a circuit housing surrounding the integrated circuit.

10. The integrated circuit according to claim 8, wherein initializing functionality of the integrated circuit initializing the memory cells is at least partly located within a memory controller that is located outside a circuit housing surrounding the integrated circuit.

11. The integrated circuit according to claim 8, wherein initializing functionality of the integrated circuit for initializing the memory cells is at least partly located within the circuit housing, however outside a memory controller located inside a circuit housing surrounding the integrated circuit.

12. The integrated circuit according to claim 8, wherein the memory cells are set to a common resistance value by simultaneously applying a constant initializing current or constant initializing voltage to each memory cell for a period of time that is larger than a period of time used for reading or programming the memory states of the memory cells.

13. The integrated circuit according to claim 12, wherein a select device is assigned to each memory cell.

14. The integrated circuit according to claim 13, wherein the resistance value of the memory cells is controlled by using the select devices as voltage dividers.

15. The integrated circuit according to claim 1, wherein the resistivity changing cells comprise programmable metallization cells.

16. The integrated circuit according to claim 1, wherein the resistivity changing cells comprise solid electrolyte cells.

17. The integrated circuit according to claim 1, wherein the resistivity changing cells comprise phase changing cells.

18. The integrated circuit according to claim 1, wherein the resistivity changing cells comprise carbon cells.

19. The integrated circuit according to claim 1, wherein the resistivity changing cells comprise transition metal oxide cells.

20. A circuit comprising a plurality of resistivity changing means for changing its resistivity,
wherein at least two resistance ranges are assigned to each resistivity changing means, each resistance range defining a possible state of the resistivity changing means, and
wherein the circuit means is operable in a resistivity changing means initializing mode in which initializing signals are applied to the plurality of resistivity changing means, strengths and durations of the initializing signals being chosen such that the resistance of each resistivity changing means is shifted into one of the resistance ranges assigned to the resistivity changing means.

21. A memory module comprising at least one integrated circuit comprising a plurality of resistivity changing cells,
wherein at least two resistance ranges are assigned to each resistivity changing cell, each resistance range defining a possible state of the resistivity changing cell, and
wherein the integrated circuit is operable in a cell initializing mode in which initializing signals are applied to the cells, strengths and durations of the initializing signals being chosen such that the resistance of each resistivity changing cell is shifted into one of the resistance ranges assigned to the resistivity changing cell.

22. The memory module according to claim 21, wherein the memory module is stackable.

23. A method of operating an integrated circuit comprising a plurality of resistivity changing cells, the method comprising:
assigning at least two resistance ranges to each resistivity changing cell, each resistance range defining a possible state of the resistivity changing cell; and
applying initializing signals to the resistivity changing cells, strengths and durations of the initializing signals being chosen such that the resistance of each resistivity changing cell is shifted into one of the resistance ranges assigned to the resistivity changing cell.

24. The method according to claim 23, wherein the initializing signals are generated outside the integrated circuit and then supplied to the integrated circuit.

25. The method according to claim 23, wherein triggering signals trigger the integrated circuit to generate the initializing signals, the triggering signals being supplied to the integrated circuit.

26. The method according to claim 24, wherein the cells are simultaneously set to a common resistance value by applying respective initializing voltages or initializing currents to the resistivity changing cells.

27. The method according to claim 26, wherein the cells are set to a common resistance value by applying a constant initializing current or constant initializing voltage to each resistivity changing cell for a period of time that is larger than the period of time used for reading or programming the states of the resistivity changing cells.

28. The method according to claim 27, wherein a select device is assigned to each resistivity changing cell, the resistance value of the resistivity changing cells being controlled by using the select devices as voltage dividers.

29. The method according to claim 23, wherein the resistivity changing cells comprise resistivity changing memory cells.

30. A method of operating a plurality of resistivity changing memory cells, the method comprising assigning at least two resistance ranges to each resistivity changing cell, each resistance range defining a possible state of the resistivity changing cell; and
applying initializing signals to the cells, strengths and durations of the initializing signals being chosen such that the resistance of each resistivity changing cell is shifted into one of the resistance ranges assigned to the resistivity changing cell.

31. A computer program product configured to perform, when being carried out on a computing device, a method of operating an integrated circuit comprising a plurality of resistivity changing cells, the method comprising:
assigning at least two resistance ranges to each resistivity changing cell, each resistance range defining a possible state of the resistivity changing cell; and
applying initializing signals to the resistivity changing cells, strengths and durations of the initializing signals being chosen such that the resistance of each resistivity changing cell is shifted into one of the resistance ranges assigned to the resistivity changing cell.

32. A method of manufacturing an integrated circuit comprising a plurality of resistivity changing cells, the method comprising:
providing a lower part of a circuit housing;
providing an integrated circuit on the lower part of the circuit housing;
initializing the integrated circuit by supplying initializing signals or triggering signals that cause the integrated circuit to generate initializing signals to initializing terminals that are connected to the integrated circuit and that are provided on the lower part of the circuit housing,
providing an upper part of the circuit housing on the lower part of the circuit housing such that the integrated circuit is covered by the upper part of the circuit housing, and that the initializing terminals are not accessible for a user using the integrated circuit.
